(19) United States
(12) Patent Application Publication
(10) Pub. No.: US 2026/0123410 A1
(43) Pub. Date: Apr. 30, 2026

(54) Lid Design and Process for Dispensable Liquid Metal Thermal Interface Material

(71) Applicant: Apple Inc., Cupertino, CA (US)

(72) Inventors: Suk-Kyu Ryu, San Jose, CA (US); Myung Jin Yim, San Jose, CA (US); Wei Hu, Santa Clara, CA (US); Saumya K. Gandhi, San Francisco, CA (US); Matthew R. Hart, Santa Clara, CA (US); Chih-Ming Chung, Cupertino, CA (US); Jun Zhai, Cupertino, CA (US)

(21) Appl. No.: 19/178,562

(22) Filed: Apr. 14, 2025

Related U.S. Application Data
(60) Provisional application No. 63/712,151, filed on Oct. 25, 2024.

(51) Int. Cl. H01L 23/367; H01L 23/00; H01L 23/373

(52) U.S. Cl. CPC H10W 40/22; H10W 40/251; H10W 40/255; H10W 40/226; H10W 72/07351; H10W 72/07352; H10W 72/07353; H10W 72/07354; H10W 72/325; H10W 72/327; H10W 72/334; H10W 72/337; H10W 72/347; H10W 72/352; H10W 72/354; H10W 72/357; H10W 72/365; H10W 72/367; H10W 72/877; H10W 74/15; H10W 90/724; H10W 90/734

(57) ABSTRACT

Electronic structures and methods of assembly are described in which a lid with pocket sidewalls is mounted on a routing substrate such that the pocket sidewalls laterally surround an electronic component and provide a barrier to outflow of the thermal interface layer outside of the pocket sidewalls, and in particular a thermal interface layer including a liquid metal film.

### RELATED APPLICATIONS

This application claims the benefit of priority of U.S. Provisional Application No. 63/712,151, filed Oct. 25, 2024, which is incorporated herein by reference.

### BACKGROUND

### Field

Embodiments described herein relate to electronic packaging structures, and more particularly to thermal interface material integration.

### Background Information

Lids are widely used in multiple chip modules (MCMs) for a variety of reasons, such as providing mechanical integrity, hermetic sealing from environment, and thermal performance. In an exemplary implementation one or more components are surface mounted onto a module substrate, and then optionally underfilled. A lid is then secured onto the module substrate and over the component(s). Commonly, a thermal interface material (TIM) is used to both join the lid to the component(s) and to act a conduit for the transfer of heat away from the component(s). A stiffener ring can also be mounted onto the package substrate separately from or in combination with the lid. Traditional TIMs consist of highly thermally conductive solid filler particles within a polymer matrix material that provides the surface wettability and compliance of the TIM during application.

### SUMMARY

Electronic structures and methods of assembly are described. In an embodiment, an electronic structure includes a routing substrate, an electronic component bonded to the routing substrate, an underfill material spanning along sidewalls of the electronic component, and a thermal interface material (TIM) layer spanning along a top surface of the electronic component, and over a portion of the underfill material around the sidewalls of the electronic component. A lid is additionally mounted on the routing substrate, the lid including a roof and pocket sidewalls protruding from the roof toward the routing substrate, where the pocket sidewalls laterally surround the electronic component and provide a barrier to outflow of the TIM layer outside of the pocket sidewalls. In one configuration the lid is bonded to the TIM layer along the top surface of the electronic component. For example, the TIM layer may be a liquid metal TIM layer, or a hybrid TIM layer including a liquid metal film and a peripheral polymeric film that surrounds the liquid metal film. In one configuration the lid includes an opening in the lid roof within an interior area of the pocket sidewalls, and a heat sink is mounted on the TIM layer within the opening.

### BRIEF DESCRIPTION OF THE DRAWINGS

FIG. 1 is a bottom isometric view illustration of a lid with pocket sidewalls in accordance with an embodiment.

FIG. 2 is a bottom isometric view illustration of a lid with pocket sidewalls and perimeter support walls in accordance with an embodiment.

FIG. 3 is a schematic bottom view illustration of perimeter support walls with vent openings in accordance with an embodiment.

FIGS. 4A-4B are schematic cross-sectional side view illustrations of an electronic structure including a lid with pocket sidewalls bonded to a thermal interface material along a top surface of an electronic component in accordance with embodiments.

FIG. 4C is a schematic top-down view illustration of a thermal interface material confined within pocket sidewalls in accordance with an embodiment.

FIGS. 5A-5B are schematic cross-sectional side view illustrations of an electronic structure including a lid with pocket sidewalls bonded to a hybrid thermal interface material along a top surface of an electronic component in accordance with embodiments.

FIG. 5C is a schematic top-down view illustration of a hybrid thermal interface material layer confined within pocket sidewalls in accordance with an embodiment.

FIG. 6 is a bottom isometric view illustration of a lid with pocket sidewalls and an opening through a roof of the lid within an interior area of the pocket sidewalls in accordance with an embodiment.

FIG. 7 is a bottom isometric view illustration of a lid with pocket sidewalls, perimeter support walls and an opening through a roof of the lid within an interior area of the pocket sidewalls in accordance with an embodiment.

FIG. 8 is an isometric exploded view illustration of an electronic structure including multiple electronic components, a stiffener structure and lid with pocket sidewalls and an opening through a roof of the lid within an interior area of the pocket sidewalls in accordance with an embodiment.

FIG. 9 is a schematic cross-sectional side view illustration of an electronic structure including multiple electronic components, a stiffener structure and lid with pocket sidewalls and an opening through a roof of the lid within an interior area of the pocket sidewalls in accordance with an embodiment.

### DETAILED DESCRIPTION

Embodiments describe electronic structures and methods of assembly in which a thermal interface material (TIM) is integrated to transfer heat away from an electronic component, such as a system on chip (SOC), and to a metal lid structure, heat sink or other cooling system.

In one aspect, it has been observed that as additional devices are integrated into increasingly small form factors that next generation systems cannot meet thermal requirements with existing filled polymer thermal interface materials. However, higher thermal conductivity materials have corresponding integration challenges. Liquid metal materials, commonly based on gallium alloys, have high characteristic thermal conductivity, ability to spread across a variety of surfaces such as silicon, copper, nickel, gold and glass, and do not solidify at room temperature. Liquid metals, and pastes thereof, can also be applied using suitable techniques such as brushing, dispensing, and jetting, while viscosity can be controlled with various additives. However, pump-out of a liquid metal TIM due to thermal stress or mechanical load can be problematic since pumped out metal particles can freely move, leading to electrical short failure or corrosion of neighboring components, and in particular any aluminum containing components.

In accordance with an embodiment, a lid with pocket sidewalls can be bonded to an electronic component (e.g., SOC, etc.) with a liquid metal TIM to mitigate liquid metal pump-out issues. The protruding pocket sidewalls surrounding the SOC die can confine metal particles from the liquid metal TIM within the pocket, preventing particles from contacting neighboring components on the same multi-chip module. A hybrid TIM pattern (liquid metal and peripheral polymeric film) can also be implemented. The peripheral polymeric film TIM is of importance in two aspects. First, the peripheral polymeric film can significantly reduce the pump-out stress during reflow. Second, the selected polymeric TIM can be fast speed and low temperature curable, which can quickly solidify and form a barrier when co-cured with the liquid metal TIM during the lid attach process. In addition, the peripheral polymeric film TIM still has decent thermal conductivity and can cover non-hot zones of the SOC, where the SOC thermal performance is boosted with the liquid metal TIM covering hot zones. A further mitigation option is the implementation of an adhesive polymeric sealing material between the pocket sidewalls and the routing substrate as an additional barrier to confine metal particles.

In accordance with an embodiment, an electronic structure includes a lid with pocket sidewalls and an opening through the roof of the lid within an interior area of the pocket sidewalls. The lid can be mounted so that the pocket sidewalls surround the electronic component and mitigate liquid metal pump-out issues, while the opening provides access to the electronic component and a liquid metal TIM layer thereon. This can allow direct placement of a heat sink onto the TIM layer on the top surface of the electronic component, thereby eliminating multiple intermediate layers to the heat transfer path. The liquid metal TIM can also directly contact the pocket sidewalls, forming a grounding enclosure around the electronic component, thus assisting electromagnetic interference (EMI) desense performance. Furthermore, by decoupling thermal performance of the lid from over the electronic component, the lid materials can be modified away from traditional copper materials to other materials such as stainless steel, where the coefficient of thermal expansion (CTE) and clastic modulus can be tuned to improve the overall mechanical performance of the electronic structure.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “above”, “over”, “to”, “between”, “spanning” and “on” as used herein may refer to a relative position of one layer with respect to other layers. One layer “above”, “over”, “spanning” or “on” another layer or bonded “to” or in “contact” with another layer may be directly in contact with the other layer or may have one or more intervening layers. One layer “between” layers may be directly in contact with the layers or may have one or more intervening layers.

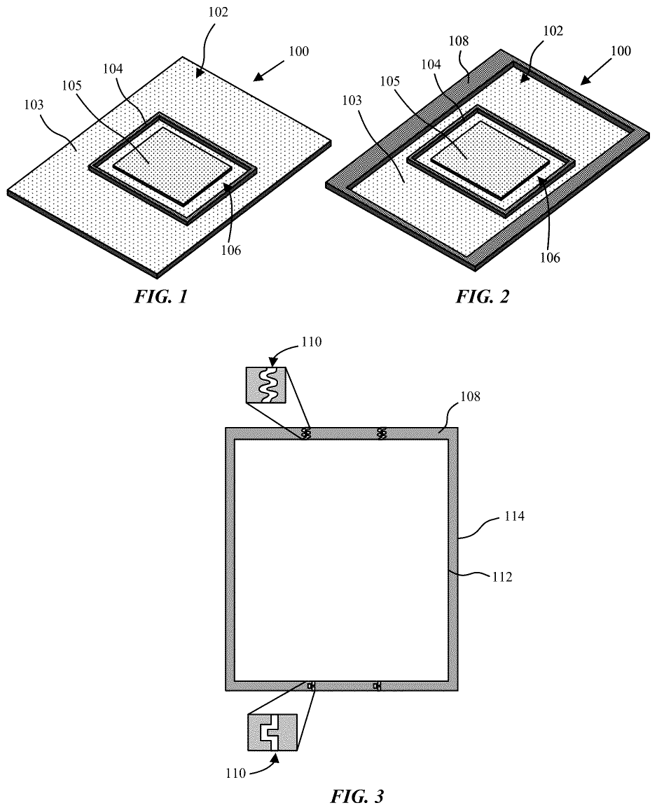

Referring now to FIGS. 1-2, FIG. 1 is a bottom isometric view illustration of a lid with pocket sidewalls in accordance with an embodiment; FIG. 2 is a bottom isometric view illustration of a lid with pocket sidewalls and perimeter support walls in accordance with an embodiment. In each of the illustrated embodiments, lid 100 can include a roof 102 and pocket sidewalls 104 that protrude from a bottom side of the roof 102 to define a pocket 106 cavity that is laterally surrounded by the pocket sidewalls 104. In an embodiment, the roof 102 bottom side from which the pocket sidewalls 104 protrude is flat. In the embodiment illustrated the roof has multiple thicknesses, including a recessed surface 103 and a thicker contact surface 105. As shown, the pocket sidewalls 104 can protrude from the recessed surface 103. The lid 100 may optionally have additional structure, though this is not required. For example, in the embodiment illustrated in FIG. 2, perimeter support walls 108 also extend from the bottom side of the roof 102. The perimeter support walls 108 may for example be used for mounting the lid onto a routing substrate or stiffener structure. The perimeter support walls 108 may be the same height as the pocket sidewalls 104, shorter than the pocket sidewalls 104 (for example, when mating with a stiffener structure), or taller than the pocket sidewalls 104.

The perimeter support walls 108 may also include vent openings to allow for out-gassing, for example during lid attach and optional cure of various components underneath the lid. FIG. 3 is a schematic bottom view illustration of perimeter support walls 108 with vent openings 110 in accordance with an embodiment. As shown, the vent openings 110 can extend through a width of the perimeter support walls 108 from an interior surface 112 to exterior surface 114. Furthermore, the vent openings may follow non-linear paths, such as zig-zag, serpentine, etc. such that the vent openings 110 do not include a straight line of sight between opposite ends of the vent openings at interior surface 112 and exterior surface 114. Such a configuration may provide a path for outgassing while impeding pump-out of various bonding materials. In some embodiments the vent openings can be formed through a stiffener structure.

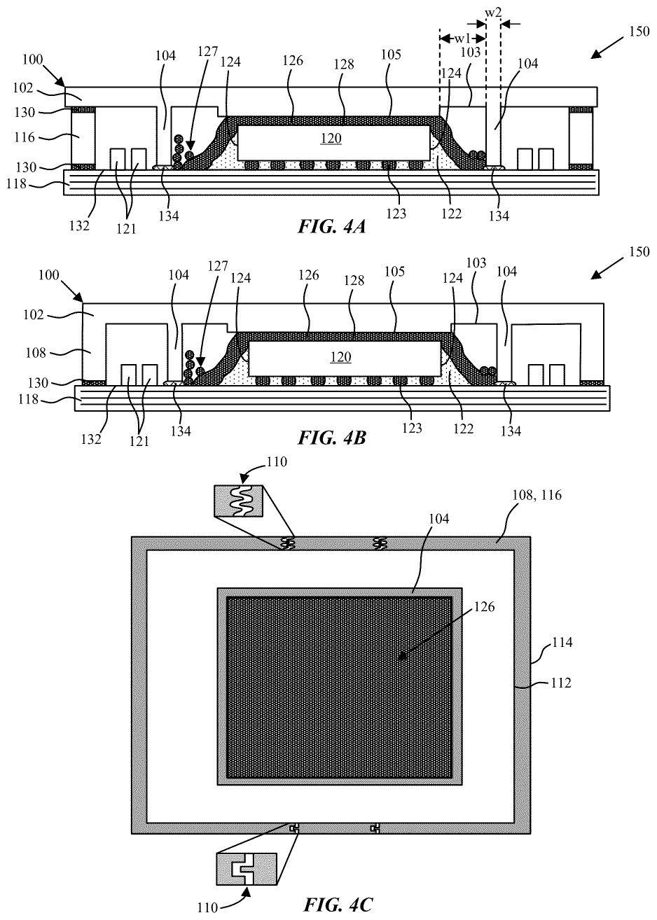

Referring now to FIGS. 4A-4B, schematic cross-sectional side view illustrations are provided for an electronic structure 150 including a lid 100 with pocket sidewalls 104 bonded to a thermal interface layer along a top surface of an electronic component in accordance with embodiments. The lid 100 and mounting methods may vary. For example, in the embodiment illustrated in FIG. 4A, the lid 100 may resemble the lid 100 of FIG. 1, and the lid may be further mounted onto a stiffener structure 116. In the embodiment illustrated in FIG. 4B, the lid 100 may resemble the lid 100 of FIG. 2, and the lid may be further mounted onto the routing substrate 118 with perimeter support walls 108.

In the illustrated embodiments, the electronic structure 150 includes a routing substrate 118, an electronic component 120 bonded to the routing substrate, an underfill material 122 (e.g., epoxy, etc.) spanning underneath the electronic component and along sidewalls 124 of the electronic component, and a thermal interface material (TIM) layer 126 spanning along a top surface 128 of the electronic component and over a portion of the underfill material around the sidewalls of the electronic component. As shown, the contact surface 105 of the lid 100 can be bonded to the TIM layer 126 along the top surface 128 of the electronic component 120. The lid 100 additionally may include a roof 102 and pocket sidewalls 104 protruding from the roof toward the routing substrate 118, where the pocket sidewalls 104 laterally surround the electronic component 120 and provide a barrier to outflow of the TIM layer 126, and particles or liquid droplets 127 thereof, outside of the pocket sidewalls 104. The TIM layer 126 can be formed of a variety of materials, including liquid metals such as Galinstan, a Ga—In—Sn alloy, or other gallium alloys due to their characteristic high thermal conductivity and wettability. In an embodiment, the TIM layer 126 includes a metallic film, and is characterized by a thermal conductivity of greater than 9.0 W/mK, greater 10.0 W/mK, or even greater than 11.0 W/mK.

The electronic component 120 can be bonded to the routing substrate 118 using suitable techniques such as flip chip bonding with solder bumps 123 (as illustrated), hybrid bonding, etc. In a hybrid bonded configuration, the underfill material may optionally be applied only along sidewalls of the electronic component, or also underneath notched edges. The electronic component 120 in accordance with embodiments can be a variety of types of components (e.g., dies). Various exemplary dies include system-on-chip (SOC), graphics processing unit (GPU), central processing unit (CPU), artificial intelligence (AI), machine learning logic, radio-frequency (RF) baseband processor, radio-frequency (RF) antenna, signal processors, power management integrated circuit (PMIC), logic, memory, photonics, biochips, low speed and/or high speed input/output (HSIO), cache, etc.

As shown, additional components 121 can be mounted on the routing substrate 118 outside a perimeter of the pocket sidewalls 104. The additional components can be a variety of passive components (e.g., capacitors, resistors, inductors) or active components such as memory or lower power processors, etc.

The routing substrate 118 in accordance with embodiments can be a variety of rigid or flexible routing substrates, including a printed circuit board (PCB) which may be cored or coreless, an interposer, etc. The routing substrate 118 may be a package substrate and may include contact pads or solder bumps on a bottom side for additional mounting onto another substrate, such as a motherboard.

Still referring to FIGS. 4A-4B, the lid 100 can be mounted onto the routing substrate 118 along with an optional stiffener structure 116, or be mounted directly onto the routing substrate 118 with optional perimeter support walls 108. Various bonding layers 130 (e.g., polymers, solder, metal alloys) can be used for bonding of the lid 100 and/or stiffener structure 116. The pocket sidewalls 104 may optionally hang above a top surface 132 of the routing substrate 118, or be bonded to the top surface 132 of the routing substrate 118. In an embodiment, the pocket sidewalls 104 are bonded to the routing substrate 118 with a polymeric sealing material 134. The polymeric scaling material 134 may form a continuous seal around the electronic component 120 for example, to further prevent pump-out of metal particles of the TIM layer 126. The polymeric scaling material 134 may be formed of a variety of materials including silicones, urethanes, siloxanes and may be ultraviolet (UV) cured or thermally cured at low temperatures such as below 130° C. In accordance with embodiments, it has been observed that bonding of the pocket sidewalls 104 to routing substrate 118 with the sealing material 134 in order to contain the TIM layer 126 can cause stress in the lid 102. In accordance with embodiments, the roof recesses, and in particular the recessed surface 103 of the lid can partly decouple stress can translate from the lid 102 to the electronic component 120. In some embodiments a first width (w1) of the recessed surface 103 between the contact surface 105 and the pocket sidewalls 104 is greater than a second width (w2) of the pocket sidewalls 104. The first width w1 may be greater than the second width w2 around one or more, or all sides of the electronic component 120. It is to be appreciated that while relative widths of w1, w2 are only labeled in FIG. 4A that the relative widths are compatible with all embodiments herein, and the relative widths are not labeled in each figure in order to not obscure other features. Furthermore, w1 and w2 may be variable around one or more sides of the electronic component 120.

FIG. 4C is a schematic top-down view illustration of a TIM layer 126 confined within pocket sidewalls 104 in accordance with an embodiment. As shown, the TIM layer 126 may spread all the way to, and touch the pocket sidewalls 104. As shown in the close-up views of the vent openings 110, the vent opening patterns may be shaped to not include a straight line of sight from one side to another of either the stiffener structure 116 or perimeter support walls 108. The vent openings 110 need not be formed through an entire thickness or height of the stiffener structure 116 or perimeter support walls 108, and may be formed across a bottom side, top side, middle, or entire height of the stiffener structure 116 or perimeter support walls 108. When formed in a bottom surface used to bond to the routing substrate, a height of the vent openings 110 needs to be sufficient so as to not be completely filled by the bonding layer 130.

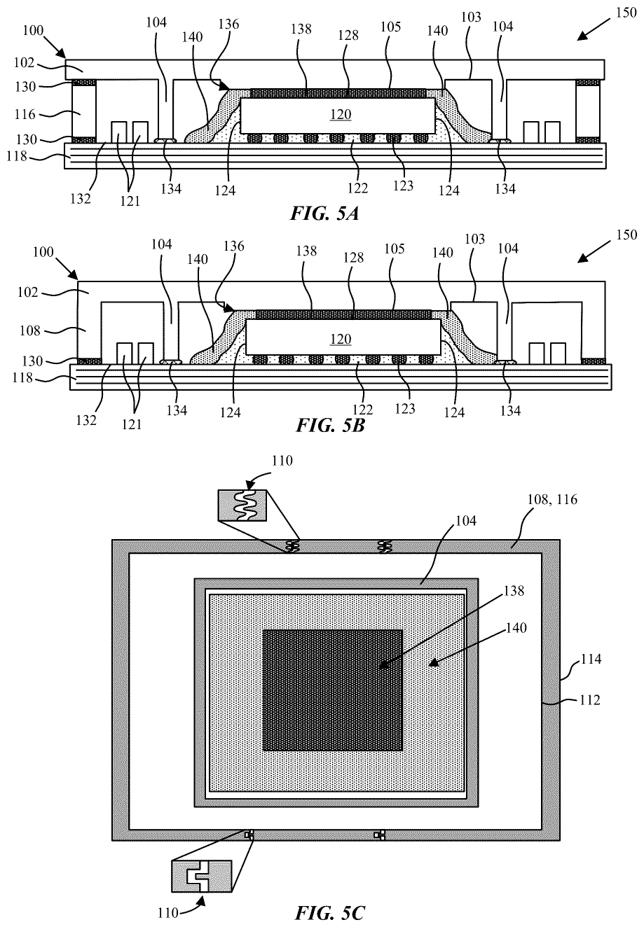

Referring now to FIGS. 5A-5C cross-sectional side view illustrations and a top-down view illustration are provided similar to those of FIGS. 4A-4C, with one difference being the inclusion of a hybrid TIM layer 136 the top surface 128 of the electronic component 120. In such configurations, the hybrid TIM layer 136 can include a metallic film 138 and a peripheral polymeric film 140 that laterally surrounds the metallic film 138. The metallic film 138 can be formed of the same materials as previously described TIM layer 126. For example, the metallic film can be a liquid metal, formed of materials such as gallium alloys such as Ga—In—Sn alloys. The peripheral polymeric film 140 in accordance with embodiments can be designed for both sealing and thermal conductivity, may be optionally filled (e.g., metal particle fillers, etc.) to improve thermal conductivity, and also may include a polymer matrix material such as a silicone, urethane, siloxane, etc. and may be UV cured or thermally cured at low temperatures such as below 130° C. In an embodiment the metallic film is characterized by a thermal conductivity of greater than 10.0 W/mK, and the peripheral polymeric film is characterized by a thermal conductivity of greater than 5.0 W/mK. In an embodiment the metallic film 138 is entirely confined above the top surface 128 of the electronic component 120, and the peripheral polymeric film 140 covers the portion of the underfill material 122 that is around the sidewalls 124 of the electronic component 120. While not required, the peripheral polymeric film 140 can contact at least one pocket sidewall 104, or all pocket sidewalls of the lid 100. In some embodiments, the peripheral polymeric film 140 does not contact any of the pocket sidewalls 104 in order to not disturb the lid attachment. The pocket sidewalls 104 may be suspended above the routing substrate 118, contact the routing substrate 118, or be bonded to the routing substrate with a polymeric scaling material 134 as previously described. Vent openings 110 may optionally be provided through the peripheral support walls 108 or stiffener structure 116 as previously described.

Up until this point, lid 100 structures have been described in which pocket sidewalls 104 are included to inhibit pump-out of TIM layer materials that are also used for bonding to an underside of the lid roof 102. In other embodiments one or more openings can be formed through a thickness of the roof 102 to allow for bonding of external components, such as a heat sink to the TIM layer.

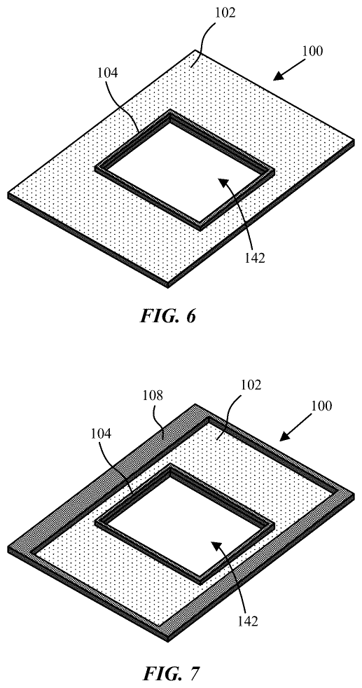

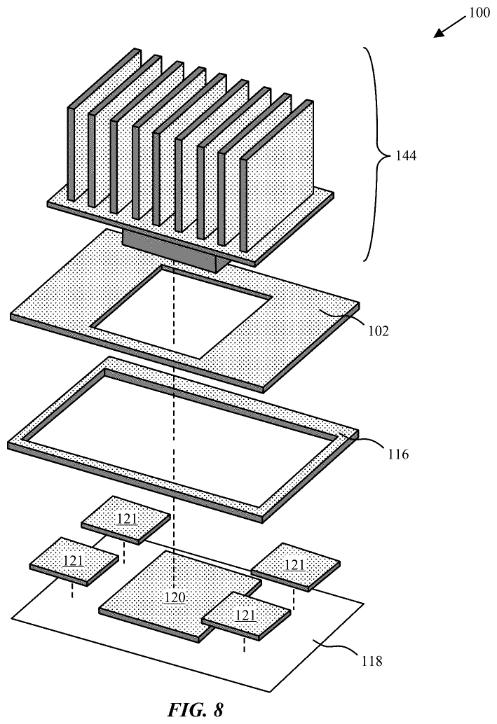

Referring now to FIGS. 6-7 bottom isometric view illustrations are provided for a lid with pocket sidewalls similar to FIGS. 1-2, with a difference being the addition of an opening 142 through a roof 102 of the lid within an interior area of the pocket sidewalls 104. The opening 142 may be at a variety of locations and distances from the pocket sidewalls 104, and may also be defined by the pocket sidewalls 104. Similar to the lid 100 described and illustrated with regard to FIG. 2, the lid 100 of FIG. 7 may optionally include perimeter support walls 108.

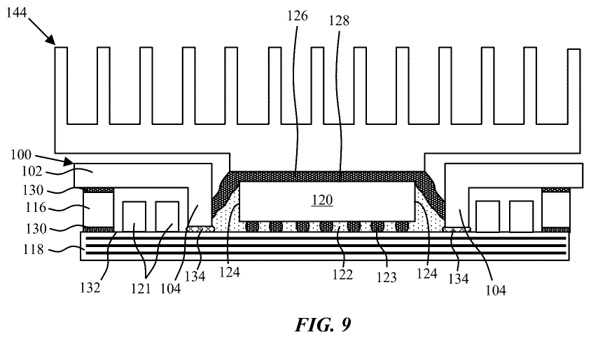

Referring now to FIGS. 8-9, isometric exploded view and cross-sectional side view illustrations are provide of an electronic structure 150 including multiple electronic components, an optional stiffener structure 116, and lid 100 with pocket sidewalls 104 and an opening 142 through a roof 102 of the lid within an interior area of the pocket sidewalls in accordance with embodiments. In an embodiment, an electronic structure includes a routing substrate 118, an electronic component 120 bonded to the routing substrate 118, an underfill material 122 spanning underneath the electronic component and along sidewalls 124 of the electronic component 120, a TIM layer 126 spanning along a top surface 128 of the electronic component 120 and over a portion of the underfill material 122 around the sidewalls 124 of the electronic component, and a lid 100 mounted on the routing substrate 118. As shown in FIGS. 8-9, the lid can include a roof 102 and pocket sidewalls 104 protruding from the roof toward the routing substrate 118, where the pocket sidewalls 104 laterally surround the electronic component 120 and provide a barrier to outflow of the TIM layer 126 outside of the pocket sidewalls. Additionally, an opening 142 may be formed through a thickness of the roof 102 within an interior area of the pocket sidewalls 104, and a heat sink 144 can be mounted on the TIM layer 126 within the opening 142 in the roof 102.

In the particular embodiment illustrated in FIGS. 8-9 the TIM layer 126 may be a metallic film, such as a liquid metal film as described herein. The TIM layer 126 may further contact at least one, multiple or all of the pocket sidewalls 104. Liquid metal in particular may have sufficient flowability, such that dispensing of a sufficient volume allows it to contact the pocket sidewalls 104 completing a Faraday cage and enabling electromagnetic interference (EMI) desense while still providing high thermal conductivity. In this configuration the TIM layer 126 and heat sink 144 can be applied after bonding of the lid 100 to the routing substrate. Similar to previous descriptions, the pocket sidewalls can be suspended above the routing substrate, contact the routing substrate, or be bonded to the routing substrate with a polymeric sealing material to further assist in containing the TIM layer 126.

In utilizing the various aspects of the embodiments, it would become apparent to one skilled in the art that combinations or variations of the above embodiments are possible for forming an electronic structure with a liquid metal thermal interface material. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. An electronic structure comprising:
a routing substrate;
an electronic component bonded to the routing substrate;
an underfill material spanning along sidewalls of the electronic component;
a thermal interface material (TIM) layer spanning along a top surface of the electronic component, and over a portion of the underfill material around the sidewalls of the electronic component; and
a lid bonded to the TIM layer along the top surface of the electronic component, the lid including a roof and pocket sidewalls protruding from the roof toward the routing substrate, wherein the pocket sidewalls laterally surround the electronic component and provide a barrier to outflow of the TIM layer outside of the pocket sidewalls.

2. The electronic structure of claim 1, wherein the TIM layer comprises a metallic film.

3. The electronic structure of claim 2, wherein the metallic film comprises a Ga—In—Sn alloy.

4. The electronic structure of claim 2, wherein the metallic film is characterized by a thermal conductivity of greater than 9.0 W/mK.

5. The electronic structure of claim 1, wherein the TIM layer comprises a metallic film and a peripheral polymeric film that surrounds the metallic film.

6. The electronic structure of claim 5, wherein the metallic film comprises a Ga—In—Sn alloy, and the peripheral polymeric film comprises a polymer matrix with metal particle filler.

7. The electronic structure of claim 5, wherein the metallic film is characterized by a thermal conductivity of greater than 9.0 W/mK, and the peripheral polymeric film is characterized by a thermal conductivity of greater than 5.0 W/mK.

8. The electronic structure of claim 5, wherein the metallic film is entirely confined above the top surface of the electronic component, and the peripheral polymeric film covers the portion of the underfill material that is around the sidewalls of the electronic component.

9. The electronic structure of claim 8, wherein the peripheral polymeric film contacts at least one pocket sidewall of the pocket sidewalls.

10. The electronic structure of claim 1, wherein the pocket sidewalls are bonded to the routing substrate with a polymeric sealing material.

11. The electronic structure of claim 1, wherein the lid further comprises perimeter support walls and a vent opening through a width of the perimeter support walls, wherein the vent opening does not include a straight line of sight between opposite ends of the vent opening.

12. The electronic structure of claim 1, further comprising a stiffener structure bonded to the routing substrate, wherein the lid is bonded to the stiffener structure, the stiffener structure includes a vent opening through a width of the stiffener structure, and the vent opening does not include a straight line of sight between opposite ends of the vent opening.

13. The electronic structure of claim 1, wherein:
a bottom side of the lid includes a recessed surface and a contact surface that is bonded to the TIM layer along the top surface of the electronic component; and
a first width of the recessed surface between the contact surface and the pocket sidewalls is greater than a second width of the pocket sidewalls.

14. An electronic structure comprising:
a routing substrate;
an electronic component bonded to the routing substrate;
an underfill material spanning along sidewalls of the electronic component;
a thermal interface material (TIM) layer spanning along a top surface of the electronic component, and over a portion of the underfill material around the sidewalls of the electronic component;
a lid mounted on the routing substrate, the lid including:
a roof;
pocket sidewalls protruding from the roof toward the routing substrate, wherein the pocket sidewalls laterally surround the electronic component and provide a barrier to outflow of the TIM layer outside of the pocket sidewalls; and
an opening in the roof, the opening within an interior area of the pocket sidewalls; and
a heat sink mounted on the TIM layer within the opening in the roof.

15. The electronic structure of claim 14, wherein the TIM layer comprises a metallic film.

16. The electronic structure of claim 15, wherein the metallic film comprises a Ga—In—Sn alloy.

17. The electronic structure of claim 15, wherein the metallic film is characterized by a thermal conductivity of greater than 9.0 W/mK.

18. The electronic structure of claim 15, wherein the metallic film contacts at least one pocket sidewall of the pocket sidewalls.

19. The electronic structure of claim 15, wherein the metallic film contacts all pocket sidewalls of the pocket sidewalls.

20. The electronic structure of claim 15, wherein the pocket sidewalls are bonded to the routing substrate with a polymeric sealing material.
